(19) United States
(12) Patent Application Publication
(10) Pub. No.: US 2025/0189355 A1
(43) Pub. Date: Jun. 12, 2025

(54) METAL STORAGE DEVICE, METAL INJECTION SYSTEM INCLUDING THE SAME, AND SUBSTRATE PROCESSING METHOD USING THE SAME

(71) Applicant: SAMSUNG ELECTRONICS CO., LTD., Suwon-si (KR)

(72) Inventors: Jaehong Lim, Suwon-si (KR); Kyoungwhan Oh, Suwon-si (KR); Ho-Youl Lee, Suwon-si (KR); Goonmo Koo, Suwon-si (KR); Juno Park, Suwon-si (KR); Youngho Hwang, Suwon-si (KR)

(21) Appl. No.: 18/794,639

(22) Filed: Aug. 5, 2024

(30) Foreign Application Priority Data
Dec. 12, 2023 (KR) 10-2023-0180112

(51) Int. Cl. G01F 23/16; G01N 29/07; H01L 21/02

(52) U.S. Cl. CPC G01F 23/161; G01N 29/07; H01L 21/02348

(57) ABSTRACT

An example metal storage device includes a storage body that defines a storage space and extends in a first direction, a heater connected to the storage body and applying heat to the storage space, and an ultrasonic measurement circuit combined with an outer surface of the storage body and transceiving an ultrasonic wave that propagates through the storage body as a medium. The ultrasonic measurement circuit includes an ultrasonic generator that generates the ultrasonic wave, and an ultrasonic receiver that receives the ultrasonic wave and spaced apart from the ultrasonic generator in the first direction and a second direction. The second direction intersects the first direction.

### CROSS-REFERENCE TO RELATED APPLICATION

This application claims priority under 35 U.S.C § 119 to Korean Patent Application No. 10-2023-0180112 filed on Dec. 12, 2023, in the Korean Intellectual Property Office, the disclosure of which is hereby incorporated by reference in its entirety.

### BACKGROUND

A semiconductor device may be fabricated through various processes. For example, the semiconductor device may be manufactured through a photolithography process, an etching process, a deposition process, and a plating process. An extreme ultraviolet (EUV) source may be used to generate an EUV radiation during an exposure process for fabricating a semiconductor device. The EUV radiation produced from the EUV source may be reflected from a reticle and irradiated to a substrate. Therefore, a pattern may be formed on the substrate.

### SUMMARY

The present disclosure relates to a metal storage device capable of measuring a volume of liquid metal stored therein even without any additional component, a metal injection system including the same, and a substrate processing method using the same.

The present disclosure relates to a metal storage device capable of measuring a volume of liquid metal by using a difference in heat capacity based on the volume of liquid metal, a metal injection system including the same, and a substrate processing method using the same.

The present disclosure relates to a metal storage device capable of measuring a volume of liquid metal by providing a storage body with an inert gas to measure a pressure of storage space, a metal injection system including the same, and a substrate processing method using the same.

The present disclosure relates to a metal storage device capable of measuring a volume of liquid metal by using a difference in arrival speed of received ultrasonic waves, a metal injection system including the same, and a substrate processing method using the same.

The object of the present disclosure is not limited to the mentioned above, and other objects which have not been mentioned above will be clearly understood to those skilled in the art from the following description.

In some implementations, a metal storage device may comprise: a storage body that provides a storage space and extends in a first direction; a heater connected to the storage body, the heater applying heat to the storage space; and an ultrasonic measurement unit combined with an outer surface of the storage body, the ultrasonic measurement unit transceiving an ultrasonic wave that propagates through the storage body as a medium. The ultrasonic measurement unit may include: an ultrasonic generator that generates the ultrasonic wave; and an ultrasonic receiver that receives the ultrasonic wave and spaced apart in the first direction and a second direction from the ultrasonic generator, the second direction intersecting the first direction.

In some implementations, a metal injection system may comprise: a metal supply device that liquefies solid metal; a metal storage device connected to the metal supply device, the metal storage device storing the liquefied metal; and a metal injection device that is supplied with liquid metal from the metal storage device, the metal injection device spraying the liquid metal. The metal storage device may include: a storage body that provides a storage space and has a first axis as a central axis, the first axis extending in a first direction; and an ultrasonic measurement unit combined with an outer surface of the storage body, the ultrasonic measurement unit transceiving an ultrasonic wave that propagates through the storage body as a medium. The ultrasonic measurement unit may include: an ultrasonic generator that generates the ultrasonic wave in the storage body; and an ultrasonic receiver opposite to the ultrasonic generator and at a level different from a level of the ultrasonic generator.

In some implementations, a substrate processing method may comprise: placing a substrate in a substrate processing apparatus; irradiating an extreme ultraviolet (EUV) radiation to the substrate; and ascertaining a remaining amount of liquid metal stored in a metal injection system of the substrate processing apparatus. The metal injection system may include: a metal supply device that liquefies solid metal; a metal storage device that is supplied with and stores the liquefied metal from the metal supply device; and a metal injection device that receives the liquid metal from the metal storage device and sprays the liquid metal. The metal storage device may include a storage body providing a storage space and having a first axis as a central axis. The first axis may extend in a first direction, The step of ascertaining the remaining amount of the liquid metal may include: introducing the liquid metal to the metal storage device; and measuring a volume of the liquid metal.

Details of other example implementations are included in the description and drawings.

### BRIEF DESCRIPTION OF THE DRAWINGS

FIG. 1 illustrates a simplified diagram showing an example of a substrate processing apparatus.

FIG. 2 illustrates a simplified diagram showing an example of a substrate processing apparatus.

FIG. 3 illustrates a perspective view showing an example of a metal injection system.

FIG. 4 illustrates a perspective view showing an example of a metal storage device.

FIG. 5 illustrates a front view showing an example of a metal storage device.

FIG. 6 illustrates a flow chart showing an example of a substrate processing method.

FIG. 7 illustrates a flow chart showing an example of a substrate processing method.

FIG. 8 illustrates a cross-sectional view showing an example of a metal storage device.

FIG. 9 illustrates a plan view showing an example of a metal storage device.

FIG. 10 illustrates a graph showing an example of an ultrasonic wave received in an ultrasonic receiver.

FIG. 11 illustrates a cross-sectional view showing an example of a metal storage device.

FIG. 12 illustrates a graph showing an example of an ultrasonic wave received in an ultrasonic receiver.

FIG. 13 illustrates a cross-sectional view showing an example of a metal storage device.

FIG. 14 illustrates a graph showing an example of an ultrasonic wave received in an ultrasonic receiver.

FIG. 15 illustrates a flow chart showing an example of a substrate processing method.

FIG. 16 illustrates a graph showing an example of a reduction in heat capacity of the storage body due to a reduction in volume of liquid metal.

FIG. 17 illustrates a graph showing power of an example of a heater for increasing a temperate of a storage body.

FIG. 18 illustrates a graph showing power of an example of a heater for increasing a temperate of a storage body.

FIG. 19 illustrates a flow chart showing an example of a substrate processing method.

FIG. 20 illustrates a graph showing an example of a volume of introduced inert gas based on discharge of liquid metal.

FIG. 21 illustrates a flow chart showing an example of a substrate processing method.

FIG. 22 illustrates a graph showing an example of a pressure of a storage space based on introduction of inert gas.

### DETAILED DESCRIPTION

The following will now describe some implementations of the present disclosure with reference to the accompanying drawings. Like reference numerals may indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. The first direction D1 and its opposite direction may be called a vertical direction. In addition, each of the second direction D2 and the third direction D3 may be called a horizontal direction.

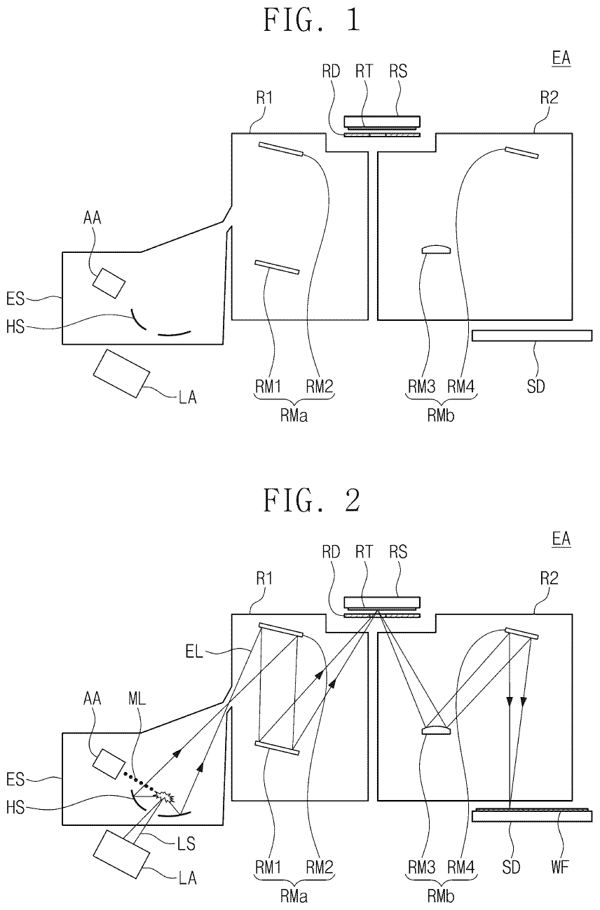

FIG. 1 illustrates a simplified diagram showing an example of a substrate processing apparatus EA. FIG. 2 illustrates a simplified diagram showing an example of the substrate processing apparatus EA.

Referring to FIG. 1, the substrate processing apparatus EA may be provided. The substrate processing apparatus EA may be an apparatus for providing a substrate WF with light to form a pattern on the substrate WF. In this description, the term “substrate” may mean a silicon (Si) wafer, but the present disclosure are not limited thereto. For example, the substrate processing apparatus EA may be configured to irradiate an extreme ultraviolet (EUV) radiation to the substrate WF and to form a pattern on the substrate WF. The substrate processing apparatus EA may include an EUV source ES, a reticle stage RS, a reticle masking device RD, a substrate stage SD, a first reflection section R1, and a second reflection section R2.

The EUV source ES may generate an EUV radiation. The EUV source ES may include a housing HS, a laser generator LA, and a metal injection system AA. The housing HS may provide an internal space in which the EUV radiation is generated. The laser generator LA may be connected to the housing HS. The laser generator LA may provide a laser to the internal space of the housing HS. The laser generator LA may emit a laser LS toward a liquid metal ML released from the metal injection system AA. The metal injection system AA may be connected to the housing HS. The metal injection system AA may provide the internal space of the housing HS with a fluid including the liquid metal ML. When the laser LS is irradiated to the fluid provided from the fluid supply device AA into the housing HS, the EUV radiation may be generated. The metal injection system AA will be discussed in detail below.

The first reflection section R1 may be positioned between the EUV source ES and the reticle stage RS and/or between the EUV source ES and the reticle masking device RD. The first reflection section R1 may guide a transit path of the EUV radiation generated from the EUV source ES. Referring to FIG. 2, the first reflection section R1 may reflect the EUV radiation, which is generated from the EUV source ES, to propagate toward the reticle stage RS and guide the EUV radiation to travel to the reticle RT. The first reflection section R1 may include a plurality of optical members RMa. For example, the first reflection section R1 may include a first optical member RM1 and a second optical member RM2. Each of the plurality of optical members RMa may include a mirror and/or a lens.

The second reflection section R2 may be positioned between the substrate stage SD and the reticle stage RS and/or between the substrate stage SD and the reticle masking device RD. The second reflection section R2 may guide a transit path of the EUV radiation that is reflected from the reticle RT. Referring to FIG. 2, the second reflection section R2 may reflect the EUV radiation, which is reflected from the reticle RT, to travel to the substrate WF on the substrate stage SD. The second reflection section R2 may include a plurality of optical members RMb. For example, the second reflection section R2 may include a third optical member RM3 and a fourth optical member RM4. Each of the plurality of optical members RMb may include a mirror and/or a lens.

The reticle stage RS may support the reticle RT. The reticle stage RS may use various ways to support the reticle RT. For example, the reticle stage RS may use an electrostatic force to rigidly place the reticle RT on a bottom surface of the reticle stage RS. In this case, the reticle stage RS may include an electrostatic chuck (ESC). The present disclosure, however, are not limited thereto, and the reticle stage RS may hold the reticle RT by using one or more of a vacuum pressure and a clamp. A pattern formed on the reticle RT on the reticle stage RS may be transferred to the substrate WF on the substrate stage SD.

The reticle masking device RD may be positioned between the EUV source ES and the reticle stage RS. The reticle masking device RD may cause the reticle RT on the reticle stage RS to receive only a portion of the EUV radiation generated from the EUV source ES. For example, the reticle masking device RD may shield another portion of the EUV radiation generated from the EUV source ES.

The substrate stage SD may support the substrate WF. For example, the substrate WF may be disposed on the substrate stage SD. The substrate stage SD may use various ways to hold the substrate WF. For example, the substrate stage SD may include an electrostatic chuck (ESC) in which an electrostatic force is used to hold the substrate WF. The present disclosure, however, are not limited thereto, and the substrate stage SD may hold the substrate WF by using one or more of a vacuum pressure and a clamp.

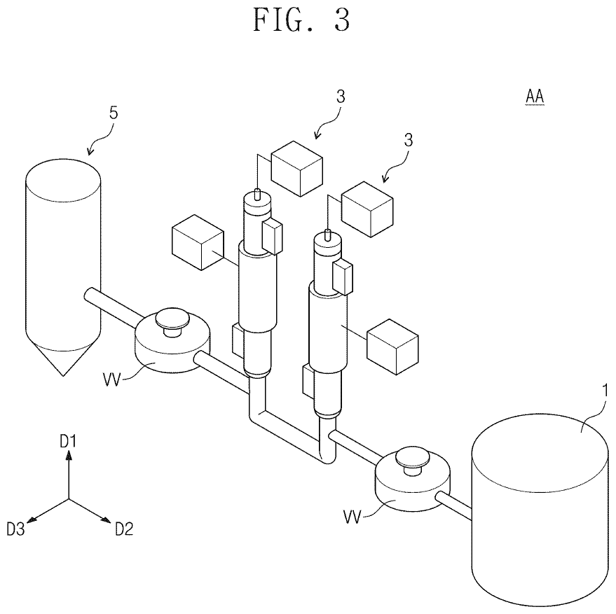

FIG. 3 illustrates a perspective view showing an example of the metal injection system AA.

Referring to FIG. 3, the metal injection system AA may include a metal supply device 1, a metal storage device 3, and a metal injection device 5. The metal supply device 1 may liquefy solid metal. In this description, the metal may include tin. The kind of metal is, however, not limited thereto. The metal supply device 1 may provides heat to liquefy the solid metal. The metal supply device 1 may raise an internal temperature to equal to or greater than about 220° C. The metal supply device 1 may supply the metal storage device 3 with the liquid metal ML. The metal storage device 3 may be connected to the metal supply device 1. The metal storage device 3 may be connected through a liquid metal valve VV to the metal supply device 1. The metal storage device 3 will be discussed below. The metal injection device 5 may be supplied with the liquid metal ML from the metal storage device 3. The metal injection device 5 and the metal storage device 3 may be connected through the liquid metal valve VV. The metal injection device 5 may spray the liquid metal ML in the form of droplets. The metal injection device 5 may spray the liquid metal ML at a frequency of about 40 kHz to about 60 KHz.

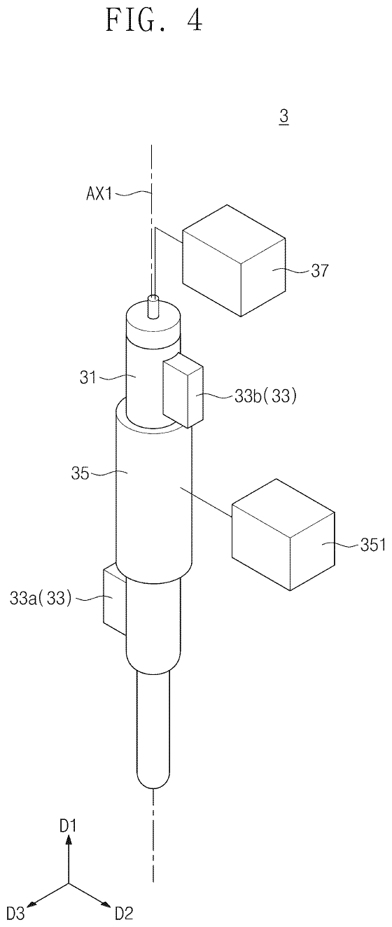

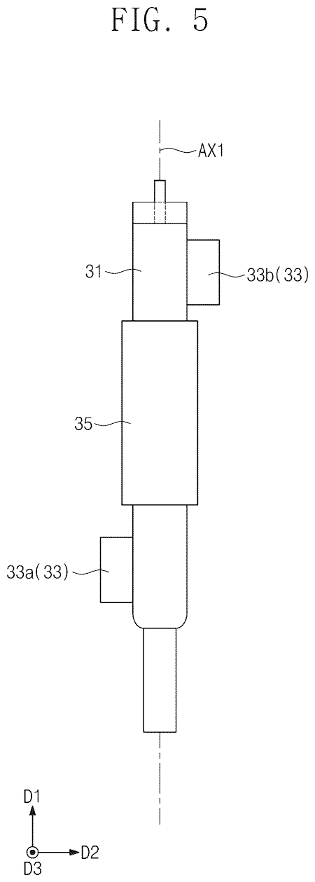

FIG. 4 illustrates a perspective view showing an example of the metal storage device 3. FIG. 5 illustrates a front view showing an example of the metal storage device 3.

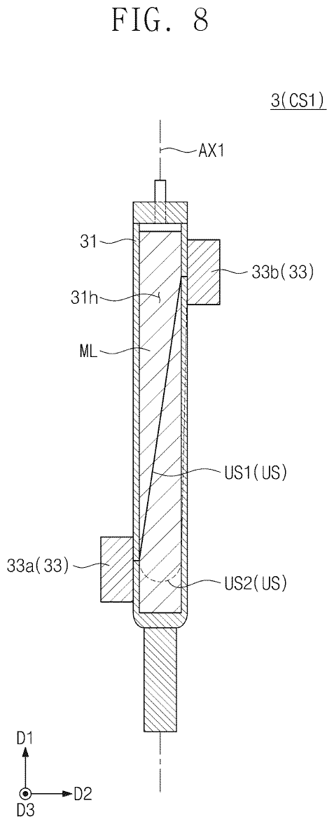

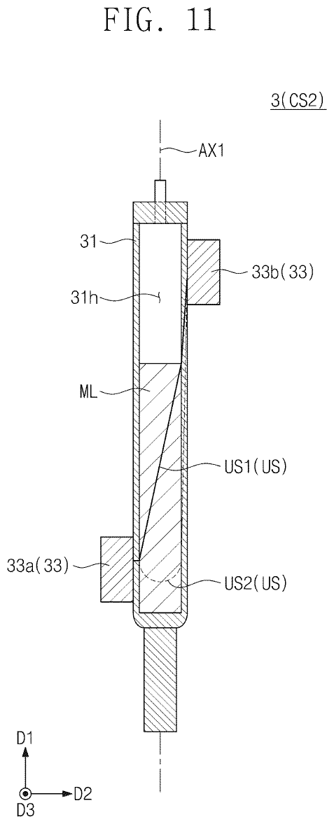

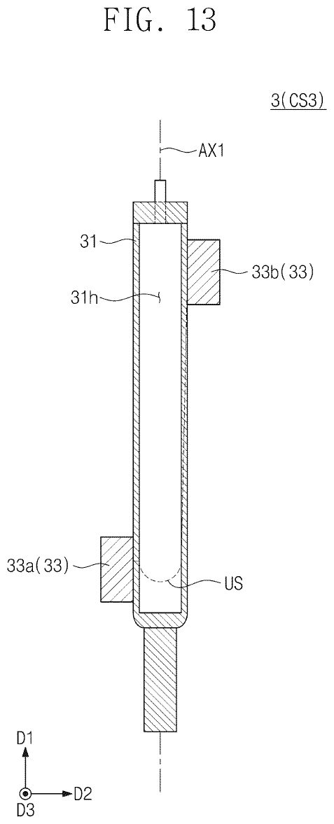

Referring to FIGS. 4 and 5, the metal storage device 3 may include a storage body 31, an ultrasonic measurement unit 33, a heater 35, a heater controller 351, a gas pump 37, and a pressure sensor. The storage body 31 may provide a storage space (see 31h of FIG. 8). The storage body 31 may have a cylindrical shape. The shape of the storage body 31, however, may not be limited thereto. The storage body 31 may include molybdenum (Mo). The storage space 31h may have a volume of about 1,000 ml to about 2,000 ml. The storage body 31 may extend in the first direction D1. The liquid metal ML may be stored in the storage space 31h. In this case, a first case (see CS1 of FIG. 8) may refer to a case where the liquid metal ML fills an entirety of the storage space 31h. A second case (see CS2 of FIG. 11) may refer to a case where the liquid metal ML fills a portion of the storage space 31h. A third case (see CS3 of FIG. 13) may refer to a case where the liquid metal ML is absent in the storage space 31h. A volume of the liquid metal ML in each of the second and third cases CS2 and CS3 may be less than that of the liquid metal ML in the first case CS1.

The ultrasonic measurement unit 33 may be combined with an outer surface of the storage body 31. The ultrasonic measurement unit 33 may transceive an ultrasonic wave US. The ultrasonic measurement unit 33 may include an ultrasonic generator 33a and an ultrasonic receiver 33b. The ultrasonic generator 33a may generate the ultrasonic wave US. The ultrasonic receiver 33b may receive the ultrasonic wave US. The ultrasonic receiver 33b may be spaced apart from the ultrasonic generator 33a in the second direction D2 that intersects the first direction D1. The ultrasonic receiver 33b may stand opposite to the ultrasonic generator 33a. The ultrasonic receiver 33b may be spaced apart in the first direction D1 from the ultrasonic generator 33a. The ultrasonic receiver 33b may be located at a level different from that of the ultrasonic generator 33a. The ultrasonic wave US may propagate through the storage body 31 as a medium. When the liquid metal ML is present in the storage body 31, the ultrasonic wave US may propagate through the liquid metal ML as a medium. The ultrasonic wave US may include a first ultrasonic wave US1 and a second ultrasonic wave US2. The first ultrasonic wave US1 may propagate through the liquid metal ML as a medium. The second ultrasonic wave US2 may propagate not through the liquid metal ML but through the storage body 31 as a medium. A speed of the first ultrasonic wave US1 may be less than that of the second ultrasonic wave US2. The ultrasonic wave US may have a frequency of equal to or less than about 6 kHz.

The heater 35 may be connected to the storage body 31. The heater 35 may apply heat to the storage space 31h. The heater 35 may heat the storage body 31. The heater 35 may surround the outer surface of the storage body 31. The heater 35 may have a power of equal to or less than about 2 kW. The heater 35 may maintain the storage body 31 at a temperature of equal to or greater than about 240° C. The power of the heater 35, however, is not limited thereto, and the heater 35 may have a power range capable of maintaining metal in a liquefied state. The heater 35 may cause the liquid metal ML to maintain its liquefied state in the storage body 31. The heater controller 351 may control the power and operating time of the heater 35.

The gas pump 37 may introduce a gas to the storage space 31h. The gas may include an inert gas. The inert gas may include nitrogen (N₂). The gas pump 37 may maintain a pressure of the storage space 31h. For example, the gas pump 37 may maintain the storage space 31h at a constant pressure. In detail, the gas pump 37 may cause the storage space 31h to maintain its pressure of equal to or greater than about 3,000 psi. The pressure of the storage space 31h, however, is not limited thereto. The pressure of the storage space 31h may depend on an amount of gas supplied by the gas pump 37 and a volume of the liquid metal ML. The gas pump 37 may include a mass flow controller (MFC) sensor. The MFC sensor may control an injection amount of fluid including the inert gas. The MFC sensor may control an injection amount of the inert gas. The MFC sensor may include one of a Coriolis mass flow sensor, a thermal mass flow sensor, and a differential-pressure mass flow sensor. The Coriolis mass flow sensor may measure a phase shift generated when a fluid passes through a tube. The Coriolis mass flow sensor may obtain a linear output proportional to flow through the phase shift. The Coriolis mass flow sensor may measure a mass flow of fluid even when information of the fluid is absent. The thermal mass flow sensor may measure a temperature change by introducing certain thermal energy to a flow of fluid. The thermal mass flow sensor may measure energy for maintaining a probe at a constant temperature. The differential-pressure mass flow sensor may use Bernoulli's principle. The differential-pressure mass flow sensor may measure a difference in fluid speed between two different points by obtaining a difference in pressure between the two different points. For example, when a hydraulic pressure at a first point is greater than that at a second point, a flow rate of fluid at the first point may be less than that at the second point. The type of the MFC sensor, however, is not limited thereto, and the MFC sensor may include any other suitable sensors capable of measuring information of fluid. The pressure of the storage space 31h may be measured by a pressure sensor. The pressure sensor may be associated with the storage body 31. The pressure sensor may have a pressure measurement range of about 200 MPa to about 2,500 MPa.

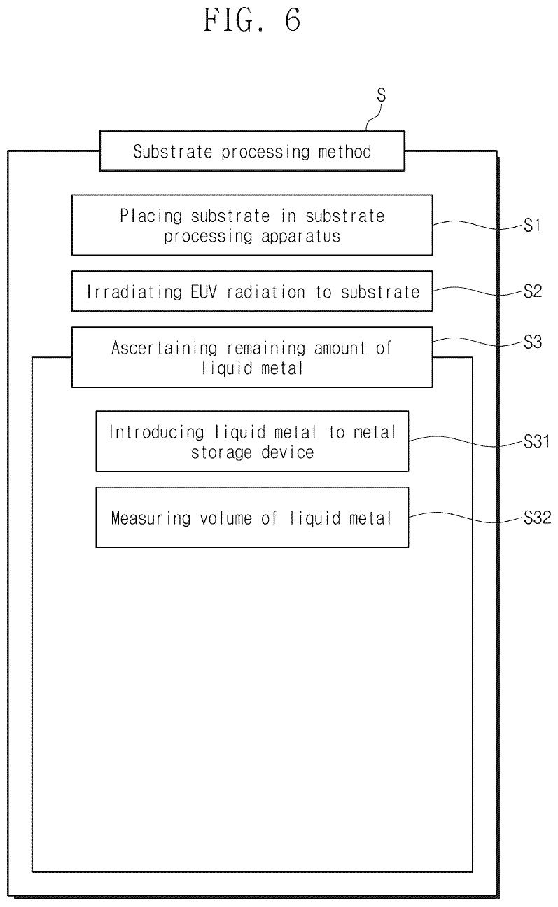

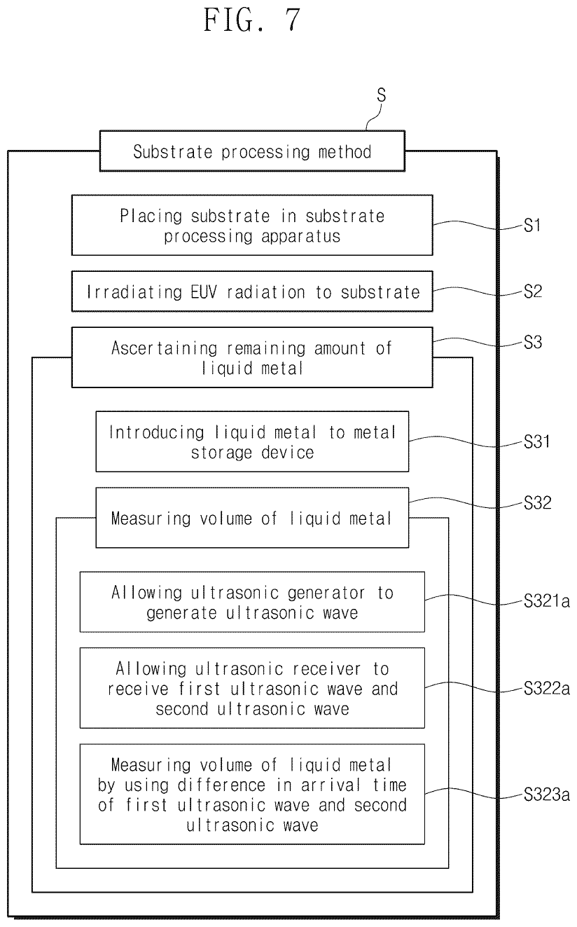

FIG. 6 illustrates a flow chart showing an example of a substrate processing method S. FIG. 7 illustrates a flow chart showing an example of the substrate processing method S.

Referring to FIG. 6, the substrate processing method S may include placing the substrate WF in the substrate processing apparatus EA (S1), irradiating the EUV radiation to the substrate WF (S2), and ascertaining a remaining amount of the liquid metal ML (S3). The amount ascertainment step S3 may include introducing the liquid metal ML to the metal storage device 3 (S31) and measuring a volume of the liquid metal ML (S32). Referring to FIG. 7, there may be provided the substrate processing method S that uses the ultrasonic measurement unit 33. The volume measurement step S32 may include allowing the ultrasonic generator 33a to generate the ultrasonic wave US (S321a), allowing the ultrasonic receiver 33b to receive the first ultrasonic wave US1 and the second ultrasonic wave US2 (S322a), and measuring a volume of the liquid metal ML by using a difference in arrival time of the first ultrasonic wave US1 and the second ultrasonic wave US2 at the ultrasonic receiver 33b (S323a).

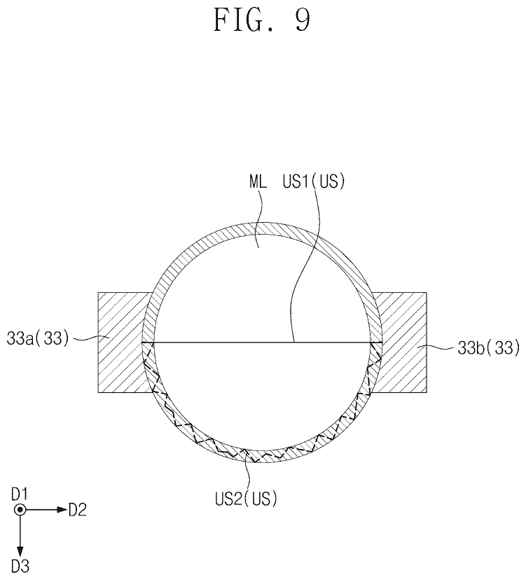

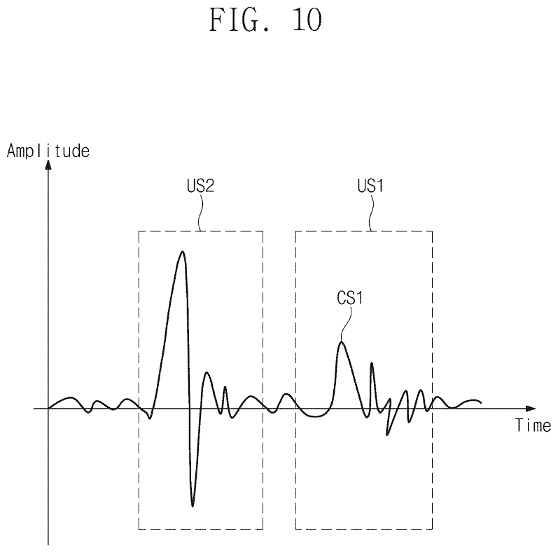

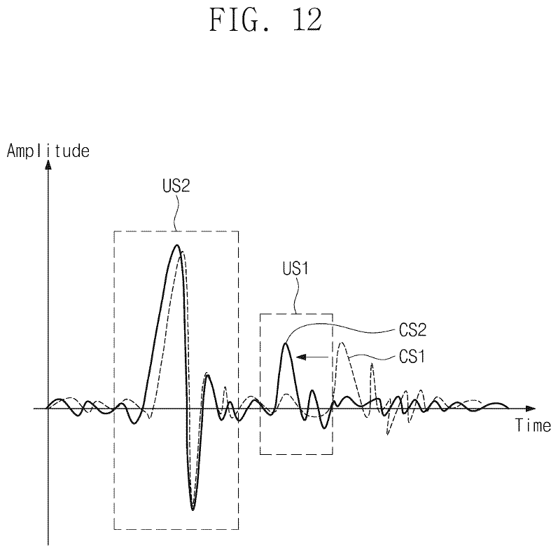

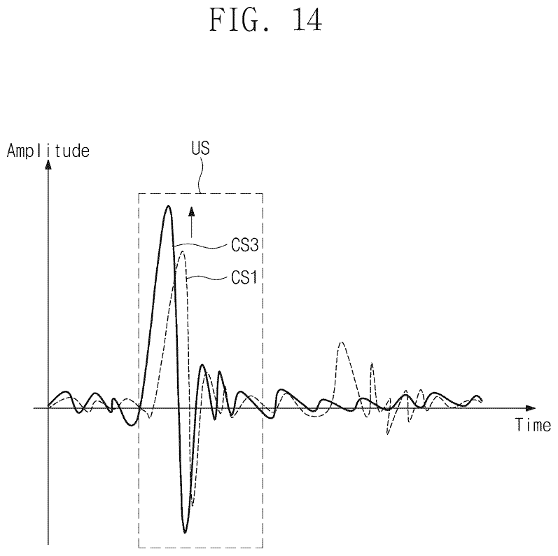

FIG. 8 illustrates a cross-sectional view showing an example of the metal storage device 3. FIG. 9 illustrates a plan view showing an example of the metal storage device 3. FIG. 10 illustrates a graph showing an example of the ultrasonic wave US received in the ultrasonic receiver 33b. FIG. 11 illustrates a cross-sectional view showing an example of the metal storage device 3. FIG. 12 illustrates a graph showing an example of the ultrasonic wave US received in the ultrasonic receiver 33b. FIG. 13 illustrates a cross-sectional view showing an example of the metal storage device 3. FIG. 14 illustrates a graph showing an example of the ultrasonic wave US received in the ultrasonic receiver 33b.

Referring to FIGS. 8, 9, and 10, there may be provided transit paths of the first ultrasonic wave US1 and the second ultrasonic wave US2 in the first case CS1, and a graph of the ultrasonic wave US received in the ultrasonic receiver 33b in the first case CS1. Referring to FIG. 8, in the first case CS1, the liquid metal ML may fill the storage space 31h. In the first case CS1, the liquid metal ML may have a top surface located at the same level as that of the ultrasonic receiver 33b. In the first case CS1, the top surface of the liquid metal ML may be located at a higher level than that of the ultrasonic receiver 33b. Referring to FIGS. 8 and 9, when the ultrasonic generator 33a generates the ultrasonic wave US, the first ultrasonic wave US1 may pass through the liquid metal ML in the storage body 31, and then may pass through the storage body 31 to reach the ultrasonic receiver 33b. The second ultrasonic wave US2 may not pass through the liquid metal ML, but may pass through only the storage body 31 to reach the ultrasonic receiver 33b. The first ultrasonic wave US1 and the second ultrasonic wave US2 may have the same frequency. The first ultrasonic wave US1 and the second ultrasonic wave US2 may propagate at the same speed through the same medium. When the first ultrasonic wave US1 and the second ultrasonic wave US2 have different media, the first ultrasonic wave US1 and the second ultrasonic wave US2 may propagate at different speeds. Referring to FIG. 10, there may be a graph showing an amplitude of the ultrasonic wave US measured in the ultrasonic receiver 33b. A horizontal axis of the graph may indicate time. A vertical axis of the graph may indicate intensity of the ultrasonic wave US. The vertical axis of the graph may mean an amplitude of the ultrasonic wave US. A speed of the second ultrasonic wave US2 that propagates passing through only the storage body 31 that is solid may be greater than that of the first ultrasonic wave US1 that passes through the liquid metal ML. The second ultrasonic wave US2 may arrive earlier than the first ultrasonic wave US1 at the ultrasonic receiver 33b. An arrival time of the first ultrasonic wave US1 and the second ultrasonic wave US2 may be determined by comparing two parts each of which has a large amplitude change in the graph. A first time may refer to a time when the first ultrasonic wave US1 arrives at the ultrasonic receiver 33b. A second time may refer to a time when the second ultrasonic wave US2 arrives at the ultrasonic receiver 33b. An amplitude change at the second time may be greater than that at the first time.

Referring to FIGS. 11 and 12, there may be the metal storage device 3 in the second case CS2 and a graph showing the first ultrasonic wave US1 and the second ultrasonic wave US2 in the second case CS2. A horizontal axis of the graph may indicate time. A vertical axis of the graph may indicate intensity of the ultrasonic wave US. The vertical axis of the graph may mean an amplitude of the ultrasonic wave US. A volume of the liquid metal ML in the second case CS2 may be less than that of the liquid metal ML in the first case CS1. In the second case CS2, the liquid metal ML may have a top surface located at a lower level than that of the ultrasonic receiver 33b. A volume of the liquid metal ML through which the first ultrasonic wave US1 can pass may be smaller in the second case CS2 than in the first case CS1. A volume of the storage body 31 through which the first ultrasonic wave US1 can pass may be larger in the second case CS2 than in the first case CS1. An arrival time of the first ultrasonic wave US1 at the ultrasonic receiver 33b may be faster in the second case CS2 than in the first case CS1. Referring to FIG. 12, the first time may be earlier in the second case CS2 than in the first case CS1. Likewise, referring to FIGS. 13 and 14, there may be provided the metal storage device 3 in the third case CS3 and a graph showing the first ultrasonic wave US1 and the second ultrasonic wave US2 in the third case CS3. A horizontal axis of the graph may indicate time. A vertical axis of the graph may indicate intensity. The vertical axis of the graph may mean an amplitude of the ultrasonic wave US. A volume of the liquid metal ML may be smaller in the third case CS3 than in the second case CS2. In the third case CS3, the liquid metal ML may have a top surface located at a lower level than that of the ultrasonic receiver 33b and that of the ultrasonic generator 33a. In the third case CS3, the liquid metal ML may have a zero volume. Referring to FIG. 14, the first time may not be found. The first ultrasonic wave US1 and the second ultrasonic wave US2 may be added to each other to cause the ultrasonic wave US to have an increased amplitude at the second time. A reduction in volume of the liquid metal ML may cause a reduction in time difference between the first time and the second time. A volume of the liquid metal ML may be measured based on the time difference between the first time and the second time. A volume of the liquid metal ML may be measured based on a difference in arrival time of the first ultrasonic wave US1 and the second ultrasonic wave US2 at the ultrasonic receiver 33b.

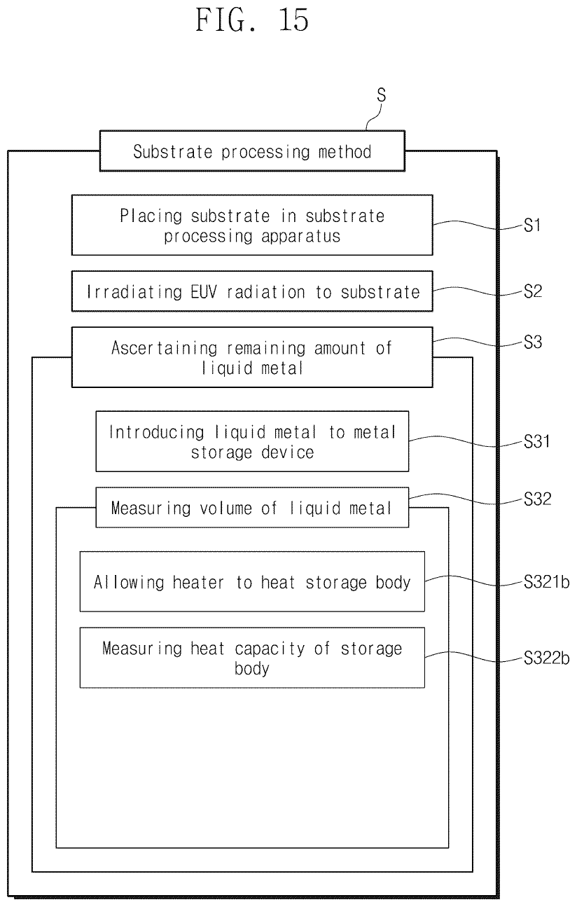

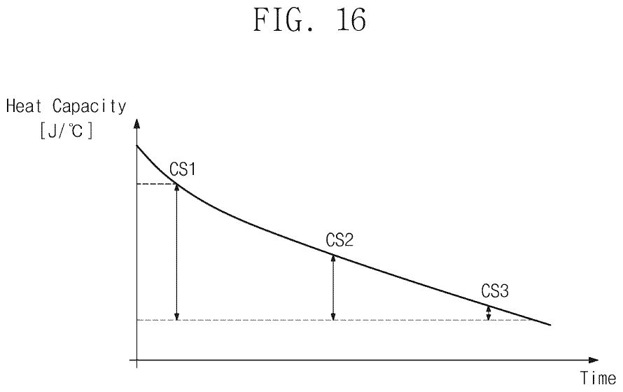

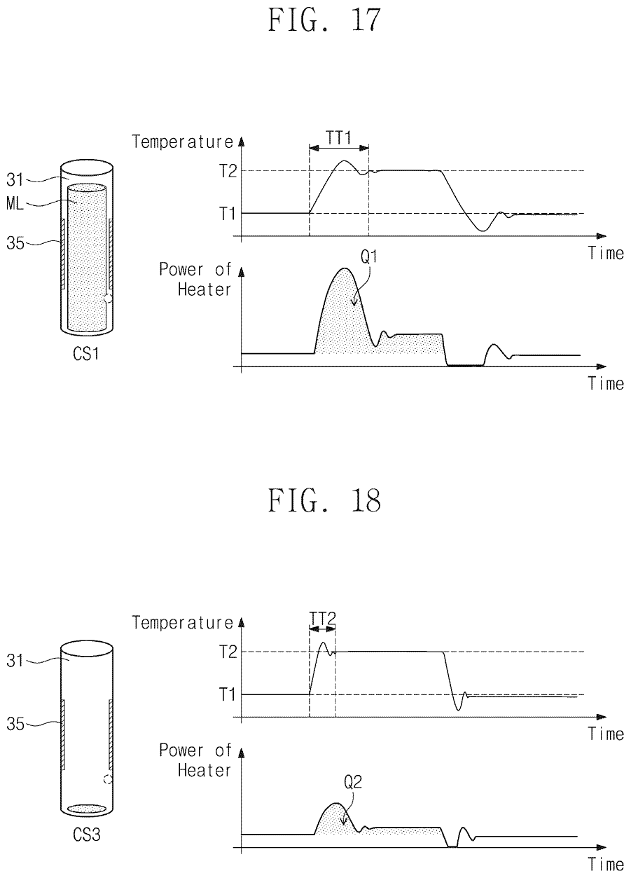

FIG. 15 illustrates a flow chart showing an example of the substrate processing method S. FIG. 16 illustrates a graph showing an example of a reduction in heat capacity of the storage body 31 due to a reduction in volume of liquid metal ML. FIG. 17 illustrates a graph showing power of an example of the heater 35 for increasing a temperate of the storage body 31. FIG. 18 illustrates a graph showing power of an example of the heater 35 for increasing a temperate of the storage body 31.

Referring to FIG. 15, the substrate processing method S may include placing the substrate WF in the substrate processing apparatus EA (S1), irradiating the EUV radiation to the substrate WF (S2), and ascertaining a remaining amount of the liquid metal ML (S3). The amount ascertainment step S3 may include introducing the liquid metal ML to the metal storage device 3 (S31) and measuring a volume of the liquid metal ML (S32). The volume measurement step S32 may include allowing the heater 35 to heat the storage body 31 (S321b) and measuring a heat capacity of the storage body 31 (S322b).

In this description, the heat capacity of the storage body 31 may be a sum of heat capacity of the storage body 31 and heat capacity of the liquid metal ML and the inert gas included in the storage space 31h. The term “heat capacity” may indicate an amount of heat required to raise the temperature of an object by 1° C. An increase in volume of the liquid metal ML may cause an increase in heat capacity of the storage body 31. When the liquid metal ML is reduced, the storage body 31 may have a reduced heat capacity. Referring to FIG. 16, there may be provided a graph showing the heat capacity of the storage body 31 when the liquid metal ML is discharged from the storage space 31h. A horizontal axis of the graph may indicate time. A vertical axis of the graph may indicate the heat capacity of the storage body 31. As the liquid metal ML is discharged from the storage space 31h, the heat capacity of the storage body 31 may also be reduced. The discharge of the liquid metal ML from the storage space 31h may cause a reduction in power of the heater 35 required for maintaining a temperature of the storage body 31. A volume of the liquid metal ML may be measured by measuring the power of the heater 35 required for maintaining a temperature of the storage body 31. Referring to FIG. 17, there may be provided a graph showing the power of the heater 35 required for raising the temperature of the storage body 31 from a first temperature T1 to a second temperature T2 in the first case CS1. Referring to FIG. 18, there may be provided a graph showing the power of the heater 35 required for raising the temperature of the storage body 31 from a first temperature T1 to a second temperature T2 in the third case CS3. A first heat amount Q1 required for raising the temperature of the storage body 31 from the first temperature T1 to the second temperature T2 in the first case CS1 may be greater than a second heat amount Q2 required for raising the temperature of the storage body 31 from the first temperature T1 to the second temperature T2 in the third case CS3. When the power of the heater 35 is constant, a first time TT1 required for raising the temperature of the storage body 31 from the first temperature T1 to the second temperature T2 in the first case CS1 may be greater than a second time TT2 required for raising the temperature of the storage body 31 from the first temperature T1 to the second temperature T2 in the third case CS3. A heat amount and time required for raising the temperature of the storage body 31 from the first temperature T1 to the second temperature T2 may be used to measure the volume of the liquid metal ML that remains in the storage space 31h.

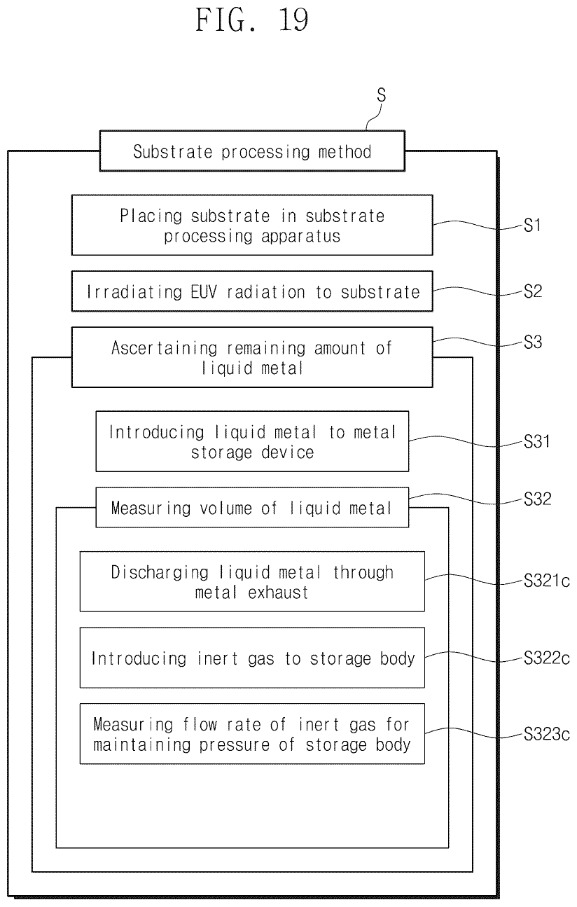

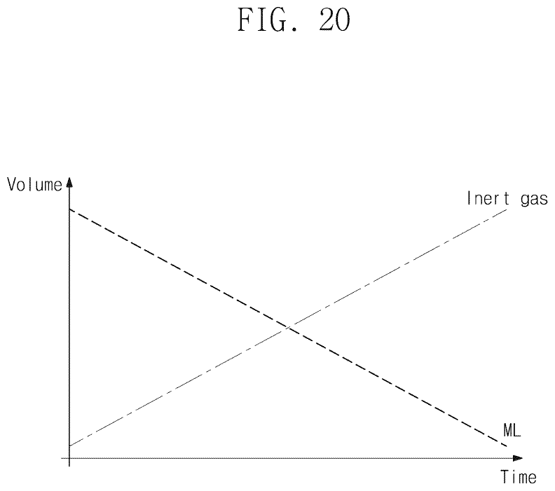

FIG. 19 illustrates a flow chart showing an example of the substrate processing method S. FIG. 20 illustrates a graph showing an example of a volume of introduced inert gas based on discharge of the liquid metal ML.

Referring to FIG. 19, the substrate processing method S may include placing the substrate WF in the substrate processing apparatus EA (S1), irradiating the EUV radiation to the substrate WF (S2), and ascertaining a remaining amount of the liquid metal ML (S3). The amount ascertainment step S3 may include introducing the liquid metal ML to the metal storage device 3 (S31) and measuring a volume of the liquid metal ML (S32). The volume measurement step S32 may include discharging the liquid metal ML from the storage space 31h (S321c), introducing an inert gas to the storage body 31 (S322c), and measuring a flow rate of the inert gas for maintaining a pressure of the storage space 31h (S323c).

Referring to FIG. 20, there may be provided a graph showing a volume of the inert gas for maintaining a pressure of the storage body 31 when the liquid metal ML is discharged from the storage space 31h. A horizontal axis of the graph may indicate time. A vertical axis of the graph may indicate volume. The storage space 31h may have a constant volume. The volume of the storage space 31h may be a sum of volumes of the liquid metal ML and the inert gas. A reduction in volume of the liquid metal ML may cause an increase in volume of the inert gas. A pressure of the storage space 31h may indicate a pressure of the inert gas. It may be needed to allow the gas pump 37 to introduce the inert gas for maintaining the storage space 31h at a constant pressure. The discharge of the liquid metal ML may cause an increase in volume of the inert gas for maintaining the storage space 31h at a constant pressure. The volume of the liquid metal ML may be measured by measuring the volume of the inert gas supplied to maintain a pressure of the storage space 31h.

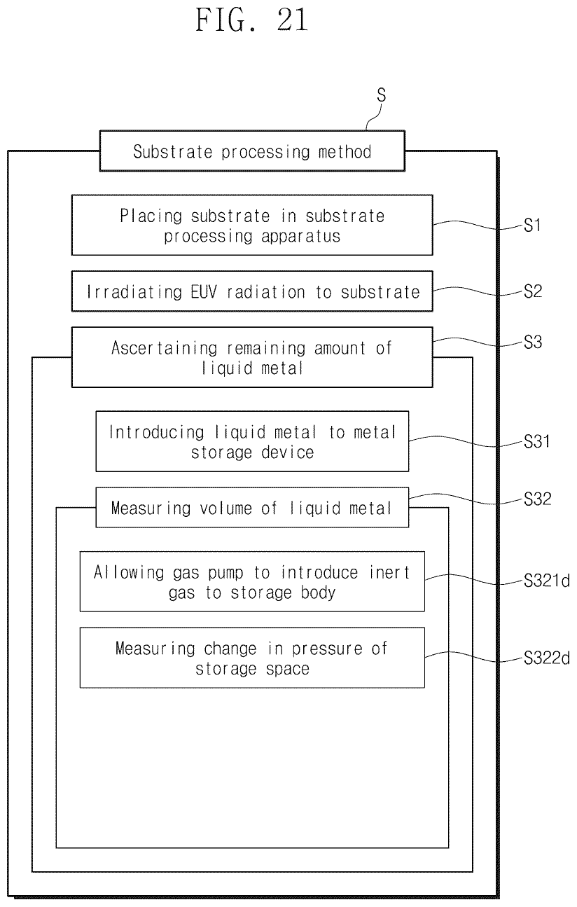

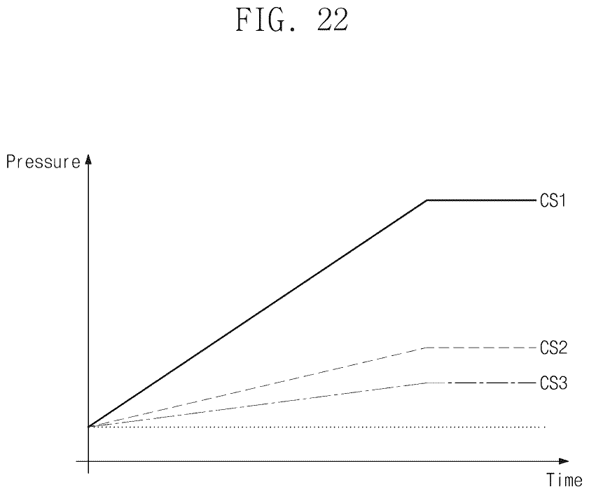

FIG. 21 illustrates a flow chart showing an example of the substrate processing method S. FIG. 22 illustrates a graph showing an example of a pressure of the storage space 31h based on introduction of inert gas.

Referring to FIG. 21, the substrate processing method S may include placing the substrate WF in the substrate processing apparatus EA (S1), irradiating the EUV radiation to the substrate WF (S2), and ascertaining a remaining amount of the liquid metal ML (S3). The amount ascertainment step S3 may include introducing the liquid metal ML to the metal storage device 3 (S31) and measuring a volume of the liquid metal ML (S32). The volume measurement step S32 may include allowing the gas pump 37 to introduce an inert gas to the storage body 31 (S321d) and measuring a change in pressure of the storage space 31h (S322d).

Referring to FIG. 22, there may be provided a graph showing a change in pressure of the storage space 31h based on an inert gas supplied to the storage space 31h when the liquid metal ML has a constant volume. A horizontal axis of the graph may indicate time. A vertical axis of the graph may indicate a pressure of the storage space 31h. The gas pump 37 may steadily supply the storage space 31h with an inert gas. When the liquid metal ML has a reduced volume, the supply of the inert gas may cause an abrupt change in pressure of the storage space 31h. In the first case CS1, there may be a maximum change in pressure of the storage space 31h. In the third case CS3, there may be a minimum change in pressure of the storage space 31h. The volume of the liquid metal ML may be measured based on a rate of change in pressure of the storage space 31h caused by introduction of the inert gas. The volume of the liquid metal ML may be measured by measuring a pressure of the storage space 31h when the inert gas is supplied for a certain time.

According to a metal storage device, a metal injection system including the same, and a metal processing method using the same in accordance with some implementations of the present disclosure, a volume of liquid metal may be measured without any additional device. The volume of liquid metal remaining in a storage space may be measured by using a heater, a heater controller, a gas pump, and a pressure sensor. A heat capacity may be used to measure the volume of liquid metal. A volume of inert gas supplied to the storage space may be used to measure the volume of liquid metal. A change in pressure of the storage space caused by the inert gas may be used to measure the volume of liquid metal. The metal injection system may be complicated therein. It is difficult to add a device in the metal injection system. An ordinary configuration may be utilized to measure the volume of liquid metal.

According to a metal storage device, a metal injection system including the same, and a metal processing method using the same in accordance with some implementations of the present disclosure, only an ultrasonic measurement unit may be added to measure a volume of liquid metal. The volume of liquid metal may be measured by using a difference in arrival time of a first ultrasonic wave and a second ultrasonic wave at an ultrasonic receiver. When other components are not operated to measure the volume of liquid metal, an ultrasonic wave may be used to measure the volume of liquid metal.

According to a metal storage device, a metal injection system including the same, and a metal processing method using the same in accordance with some implementations of the present disclosure, it may be possible to reduce maintenance cost due to oversupply or shortage of liquid metal. When a volume of liquid metal cannot be observed outside in real-time, the metal storage device may be excessively supplied with liquid metal. When no liquid metal is present in the metal storage device, the metal injection system may not be operated. The oversupply or shortage of liquid metal may have a harmful effect on the metal injection system. When it is not detected that the liquid metal is leaked from the metal storage device, excessive maintenance costs may be incurred, and a substrate processing process may be inhibited. As the volume of liquid metal is measured outside, it may be possible to manage the metal injection system and to prevent in advance problems resulting from oversupply or shortage of liquid metal.

According to a metal storage device, a metal injection system including the same, and a metal processing method using the same of the present disclosure, a volume of liquid stored in the metal storage device may be measured without any additional component.

According to a metal storage device, a metal injection system including the same, and a metal processing method using the same of the present disclosure, a volume of liquid metal may be measured by using a heat capacity difference due to the volume of liquid metal.

According to a metal storage device, a metal injection system including the same, and a metal processing method using the same of the present disclosure, a volume of liquid metal stored in a storage body may be measured by introducing an inert gas to the storage body to measure a pressure of a storage space.

According to a metal storage device, a metal injection system including the same, and a metal processing method using the same of the present disclosure, an ultrasonic wave may be transceived and a difference in arrive time of the ultrasonic wave may be used to measure a volume of liquid metal.

Effects of the present disclosure are not limited to the mentioned above, other effects which have not been mentioned above will be clearly understood to those skilled in the art from the following description.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure has been described in connection with some implementations illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A metal storage device, comprising:
a storage body defining a storage space, the storage body extending in a first direction;
a heater connected to the storage body, the heater configured to apply heat to the storage space; and
an ultrasonic measurement unit configured to be combined with an outer surface of the storage body, the ultrasonic measurement unit configured to transceive an ultrasonic wave that propagates through the storage body as a medium,
wherein the ultrasonic measurement unit includes:
an ultrasonic generator configured to generate the ultrasonic wave; and
an ultrasonic receiver configured to receive the ultrasonic wave, the ultrasonic receiver being spaced apart from the ultrasonic generator in the first direction and a second direction, the second direction intersecting the first direction.

2. The metal storage device of claim 1, wherein a power of the heater is equal to or less than 2 kW.

3. The metal storage device of claim 1, wherein the ultrasonic generator is configured to generate an ultrasonic wave with frequency being equal to or less than 6 kHz.

4. The metal storage device of claim 1, comprising:
a gas pump connected to the storage body, the gas pump configured to provide the storage space with a gas to increase a pressure of the storage space; and
a pressure sensor configured to measure the pressure of the storage space.

5. The metal storage device of claim 4, wherein
the gas pump is configured to introduce an inert gas, the inert gas including nitrogen (N₂), and
the pressure sensor has a pressure measurement range of 200 MPa to 2,500 MPa.

6. A metal storage device, comprising:
a storage body defining a storage space, the storage body including a first axis as a central axis, the first axis extending in a first direction; and
an ultrasonic measurement unit configured to be combined with an outer surface of the storage body, the ultrasonic measurement unit configured to transceive an ultrasonic wave that propagates through the storage body as a medium, and
wherein the ultrasonic measurement unit includes:
an ultrasonic generator configured to generate the ultrasonic wave in the storage body; and
an ultrasonic receiver opposite to the ultrasonic generator, the ultrasonic receiver at a level different from a level of the ultrasonic generator.

7. The metal storage device of claim 6, further comprising:
a gas pump connected to the storage body, the gas pump configured to supply an inert gas; and
a pressure sensor configured to be combined with the storage body and to measure a pressure of the storage space,
wherein a volume of the storage space is 1,000 ml to 2,000 ml, and
wherein the inert gas supplied by the gas pump includes a nitrogen gas.

8. The metal storage device of claim 7, wherein the gas pump includes a mass flow controller that is configured to control an injection amount of the inert gas.

9. The metal storage device of claim 6, wherein the metal storage device includes:
a heater configured to surround the outer surface of the storage body; and
a heater controller configured to control a power and an operating time of the heater.

10. The metal storage device of claim 9, wherein the power of the heater is equal to or less than 2 kW.

11. The metal storage device of claim 6, wherein the storage body includes molybdenum.

12. A metal storage device, comprising:
a storage body defining a storage space, the storage body including a first axis as a central axis, the first axis extending in a first direction;
a heater combined with an outer surface of the storage body, the heater being configured to apply heat to the storage space; and
a gas pump configured to introduce an inert gas to the storage body.

13. The metal storage device of claim 12,
further includes an ultrasonic measurement unit that is combined with an outer surface of the storage body, the ultrasonic measurement unit being configured to transceive an ultrasonic wave,
wherein the ultrasonic measurement unit includes:
an ultrasonic generator configured to generate the ultrasonic wave; and
an ultrasonic receiver configured to receive the ultrasonic wave, the ultrasonic receiver being spaced apart from the ultrasonic generator in the first direction.

14. The metal storage device of claim 12, further includes a heater controller configured to control a power and an operating time of the heater.

15. The metal storage device of claim 12,
wherein a power of the heater is equal to or less than 2 kW.

16. The metal storage device of claim 13,
wherein the ultrasonic generator is configured to generate an ultrasonic wave with frequency being equal to or less than 6 kHz.

17. The metal storage device of claim 12, further includes a pressure sensor configured to measure a pressure of the storage body,
wherein the storage body provides a metal exhaust through which the liquid metal is discharged.

18. The metal storage device of claim 17, wherein the pressure sensor has a pressure measurement range of about 200 MPa to about 2,500 MPa.

19. The metal storage device of claim 12, wherein the storage body includes molybdenum.

20. The metal storage device of claim 13, wherein a level of the ultrasonic receiver is higher than a level of the ultrasonic generator.
